(19) United States
(12) Patent Application Publication
(10) Pub. No.: US 2012/0086124 A1
(43) Pub. Date: Apr. 12, 2012

(54) SEMICONDUCTOR DEVICE AND METHOD OF MANUFACTURING THE SAME

(75) Inventor: Toshihide Yamaguchi, Kanagawa (JP)

(73) Assignee: Renesas Electronics Corporation

(21) Appl. No.: 13/253,611

(22) Filed: Oct. 5, 2011

(30) Foreign Application Priority Data
Oct. 6, 2010 (JP) 2010-226676

(51) Int. Cl. H01L 23/485; H01L 21/28

(52) U.S. Cl. 257/738; 438/614; 257/E23.021; 257/E21.158

(57) ABSTRACT

A semiconductor device according to this embodiment has an electrode (electrode pad) and an insulative film (protective resin film) formed on the electrode and having an opening for exposing the electrode. The semiconductor device further has an under bump metal (UBM layer) formed over the insulative film and connected with the electrode through the opening, and a solder ball formed over the under bump metal, and the contour line at the lower end of the solder ball is situated inside the contour line of the under bump metal, whereby generation of fracture in the insulative film caused by the stress upon mounting the semiconductor device is suppressed even when the solder ball is formed of a lead-free solder.

### CROSS-REFERENCE TO RELATED APPLICATIONS

The disclosure of Japanese Patent Application No. 2010-226676 filed on Oct. 6, 2010 including the specification, drawings and abstract is incorporated herein by reference in its entirety.

### BACKGROUND

The present invention relates to a semiconductor device and a method of manufacturing the semiconductor device.

Flip-chip connection is a technique of mounting a semiconductor device having solder balls on electrodes to a wiring substrate. In the mounting, the solder balls are opposed to the electrodes on the side of the wiring substrate and, in this state, melted by heating and then cooled. That is, a heat cycle is generated during the mounting.

Japanese Unexamined Patent Publication No. Hei 06(1994)-177134 describes a bump structure of interposing a resin layer between an electrode (terminal electrode in this patent document) and a barrier metal below the solder bump for moderating the stress generated in the solder bump by the heat cycle during mounting of an electronic part.

Japanese Unexamined Patent Publication No. 2009-212332 describes a semiconductor device of a structure in which a plurality of polyimide layers are interposed between an under bump metal and an electrode (uppermost layer metal in this patent document) and layers are made softer on the upper side in the plurality of polyimide layers.

### SUMMARY

By the way, lead-free solder with increasing demands in recent years as the material for solder balls has lower ductility compared with lead-containing solder. Therefore, when the solder balls are formed of lead-free solder, they suffer from more serious stress due to stress upon mounting of a semiconductor device compared with a case of using lead-containing solder.

When the solder ball is formed of the lead-free solder in the structure of Japanese Unexamined Patent Publication No. Hei 06(1994)-177134 or Japanese Unexamined Patent Publication No. 2009-212332, while progress of fracture in an insulative film (for example, polyimide cracking) may be moderated, it is difficult to suppress the generation of fracture per se.

As described above, when the solder ball is formed of the lead-free solder, it is difficult to suppress the generation of fracture in the insulative film caused by the stress during mounting of the semiconductor device.

According to an aspect of the present invention, there is provided a semiconductor device having an electrode, an insulative film formed over the electrode and having an opening for exposing the electrode therethrough, an under bump metal formed over the insulative film and connected through the opening with the electrode, and a solder ball formed on the under bump metal, in which the contour line at the lower end of the solder ball is situated inside the contour line of the under bump metal.

According to the aspect of the invention, since the contour line at the lower end of the solder ball formed on the under bump metal is situated inside the contour line of the under bump metal, when a stress that concentrates to the peripheral edge at the lower end of the solder ball is transmitted by way of the under bump metal to the insulating film, the stress can be moderated by the under bump metal. Accordingly, fracture in the insulative film, etc. can be suppressed and, further, generation of fracture, etc. of the film in the layers lower than the insulative film that may be triggered from the fracture in the insulative film can also be suppressed. As described above, even when the solder ball is formed of the lead-free solder, generation of the fracture in the insulative film due to the stress upon mounting of the semiconductor device can be suppressed.

According to another aspect of the present invention, there is further provided a method of manufacturing a semiconductor device including the steps of forming an insulative film over an electrode, the insulative film having an opening for exposing the electrode, forming an under bump metal so as to be connected with the electrode through the opening, and forming a solder ball over the under bump metal, in which the steps of forming the under bump metal and forming the solder ball are performed such that the contour line at the lower end of the solder ball is situated inside the contour line of the under bump metal.

According to the aspects of this invention, even when the solder ball is formed of the lead-free solder, generation of fracture in the insulative film caused by the stress during mounting of the semiconductor device can be suppressed.

### DESCRIPTION OF THE ACCOMPANYING DRAWINGS

FIG. 1 is a cross sectional view of a semiconductor device according to an embodiment;

FIG. 2 is a view showing a planar positional relationship of a contour line at the lower end of a solder ball and a contour line of an under bump metal in the semiconductor device according to the embodiment;

FIG. 3 is a cross sectional view of the semiconductor device according to the embodiment;

FIG. 4 is a cross sectional view showing a series of steps in a method of manufacturing a semiconductor device according to the embodiment;

FIG. 5 is a cross sectional view showing a series of steps in the method of manufacturing the semiconductor device according to the embodiment;

FIG. 6 is a cross sectional view showing a series of steps in the method of manufacturing the semiconductor device according to the embodiment;

FIG. 7 is a cross sectional view showing a series of steps in the method of manufacturing the semiconductor device according to the embodiment;

FIG. 8 is a cross sectional view showing a series of steps in the method of manufacturing the semiconductor device according to the embodiment;

FIG. 9 is a cross sectional view of a semiconductor device according to a comparative examination case;

FIG. 10 is a view showing a planar positional relationship between the contour line at the lower end of a solder ball of a semiconductor device and a contour line of an under bump metal in a semiconductor device according to the comparative examination case; and

FIG. 11 is a cross sectional view showing a problem in the semiconductor device according to the comparative examination case.

### DETAILED DESCRIPTION

A preferred embodiment of the invention is to be described with reference to the drawings. Throughout the drawings, identical constitutional elements carry the same reference numerals for which description is to be omitted optionally.

### FIRST EMBODIMENT

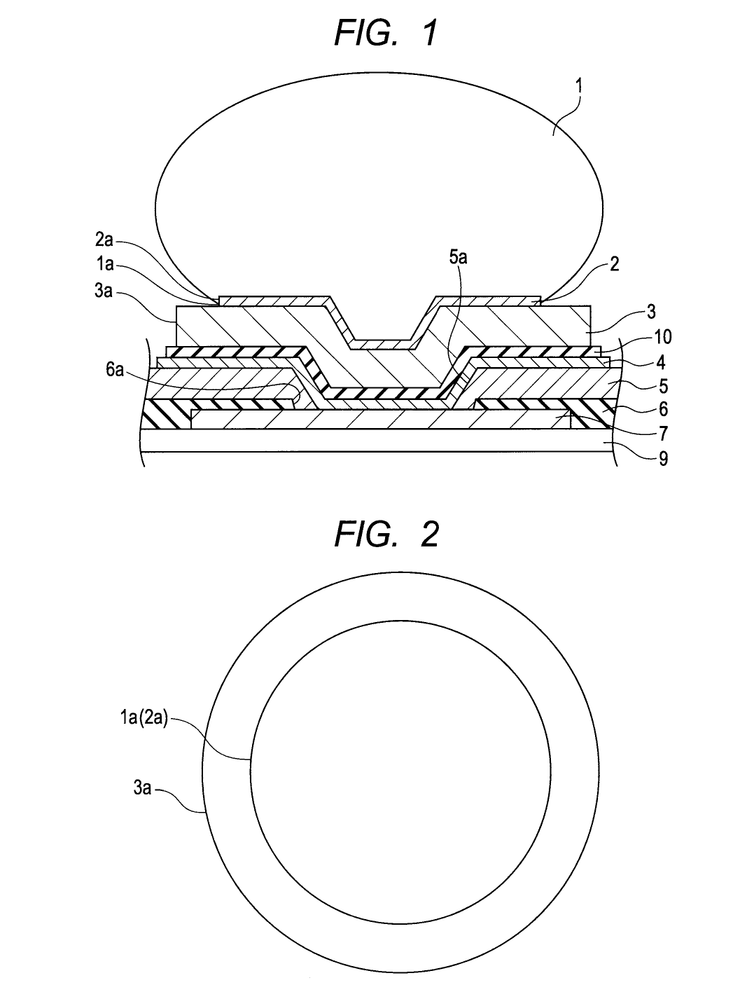

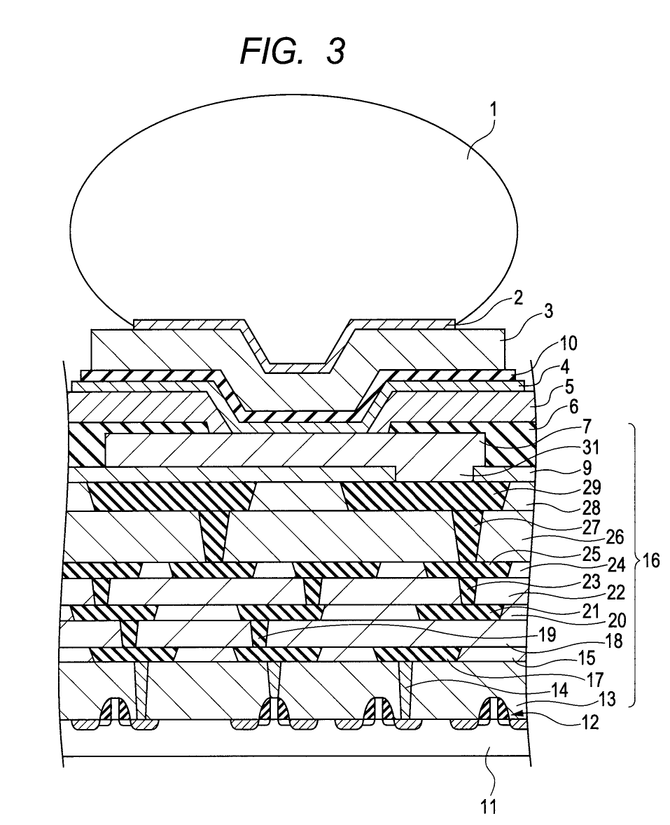

FIG. 1 and FIG. 3 are cross sectional views of a semiconductor device according to an embodiment and FIG. 2 is a view showing a planar positional relationship between a contour line 1a at the lower end of a solder ball 1 and a contour line 3a of an under bump metal of a semiconductor device according to the embodiment. The semiconductor device according to the embodiment has an electrode (electrode pad 7), an insulative film (for example, protective resin film 5) formed on the electrode and having an opening 5a for exposing the electrode, an under bump metal (UBM layer 3) formed on the insulative film and connected through the opening 5a with the electrode, and a solder ball 1 formed on the under bump metal, in which the contour line 1a at the lower end of the solder ball 1 is situated inside the contour line 3a of the under bump metal. Description is to be made specifically.

As shown in FIG. 1, uppermost layer wirings of the semiconductor device include an electrode pad 7. The uppermost layer wirings are formed on the interlayer insulative film 9 at the uppermost layer of a multi-layered wiring layer 16 of the semiconductor device (to be described later). A cover nitride film 6 is formed on the uppermost layer wirings including the electrode pad 7, and an opening 6a for exposing the electrode pad 7 is formed in the cover nitride film 6. A protective insulative film 5 is formed on the cover nitride film 6 and on the electrode pad 7 in the opening 6a, and an opening 5a for exposing the electrode pad 7 is formed in the protective resin film 5. A Ti film 4 as a barrier metal is formed on the protective resin film 5 and on the electrode pad 7 in the opening 5a. A Cu film 10 is formed on the Ti film 4. The UBM layer 3 is formed on the Cu film 10.

The UBM layer 3 is, for example, an Ni layer.

A metal film is formed on the UBM layer 3. The metal film is formed of a material having a wettability to the solder (solder ball 1) which is higher than that of the UBM layer 3. Specifically, the metal film is, for example, a Cu film 2. As shown in FIG. 2, the contour line 2a of the Cu film 2 is situated inside the contour line 3a of the UBM layer 3. The solder ball 1 is disposed so as to be in contact over the entire surface of the Cu film 2 and so as not to extend outward beyond the Cu film 2. Accordingly, as shown in FIG. 2, the contour line 1a at the lower end of the solder ball 1 is also situated inside the contour line 3a of the UBM layer 3. In other words, the UBM layer 3 extends as far as the outside of the contour line 1a at the lower end of the solder ball 1. In this embodiment, the contour line 1a at the lower end of the solder ball 1 corresponds to the contour line for the joined face between the solder ball 1 and the Cu film 2 therebelow.

In this case, the diameter of the UBM layer 3 is preferably larger by 10 μm or more than the diameter at the lower end of the solder ball 1. Further, the diameter of the UBM layer 3 is preferably 1.1 times or more the diameter at the lower end of the solder ball 1. Further, the solder ball preferably is situated at the center of the UBM layer 3.

The solder ball 1 may also be formed of lead solder or lead-free solder. The lead-free solder includes, for example, Sn—Ag solder or Sn—Ag—Cu solder.

Then, the configuration below the uppermost layer wirings is to be described with reference to FIG. 3.

Transistors 12 are formed to a substrate 11 such as a silicon substrate, and an interlayer insulative film 13 at the lowermost layer is formed over the substrate 11 so as to cover the transistors 12. The interlayer insulative film 13 is formed, for example, of SiO₂. Contacts 14 are buried in the interlayer insulative film 13.

A wiring layer insulative film 15 is formed on the interlayer insulative film 13 and wirings 17 at the lowermost layer of a multi-layered wiring layer 16 are buried in the wiring layer insulative film 15. The transistors 12 are electrically connected by way of the contacts 14 to the wirings 17 at the lowermost layer of the multi-layered wiring layer 16.

An interlayer insulative film 18 is formed on the wiring layer insulative film 15 and via holes 19 are buried in the interlayer insulative film 18. A wiring layer insulating film 20 is formed on the interlayer insulative film 18 and wirings 21 are buried in the wiring layer insulative film 20. An interlayer insulative film 22 is formed on the wiring layer insulative film 20 and via holes 23 are buried in the interlayer insulative film 22. A wiring layer insulative film 24 is formed on the interlayer insulative film 22 and wirings 25 are buried in the wiring layer insulative film 24. An interlayer insulative film 26 is formed on the wiring layer insulative film 24 and via holes 27 are buried in the interlayer insulative film 26. A wiring layer insulative film 28 is formed on the interlayer insulative film 26 and wirings 29 are buried in the wiring layer insulative film 28. An interlayer insulative film 9 is formed on the wiring layer insulative film 28 and a via hole 31 is buried in the interlayer insulative film 9. Then, uppermost layer wirings including the electrode pad 7 are formed on the interlayer insulative film 9.

The uppermost layer wirings (including the electrode pad 7) and the via hole 31 in the uppermost layer are formed, for example, of Al, and other wirings and via holes (wirings 29, 25, 21, 17, and via holes 27, 23, 19) are formed of Cu.

Further, the interlayer insulative films 18, 22 and the wiring layer insulative films 15, 20, 24 are preferably formed of a Low-k film (low dielectric constant insulative film). The Low-k film is used for decreasing the capacitance between the multi-layered wirings for connecting the semiconductor device and means those materials with lower specific dielectric constant than that of a silicon oxide film (specific dielectric constant: 3.9 to 4.5). The Low-k film may also be a porous insulative film. The porous insulative film includes, for example, those materials formed by making a silicon oxide film porous thereby lowering the specific dielectric constant or those materials formed by making HSQ (hydrogen silsesquioxane) film, organic silica film, SiOC (for example, Black Diamond™, CORAL™, Aurora™) porous thereby lowering the specific dielectric constant.

The interlayer films 26, 9 and the wiring layer insulative film 28 are formed, for example, of SiO₂. The cover nitride film 6 is formed, for example, of SiON.

The protective resin film 5 is, for example, a polyimide film.

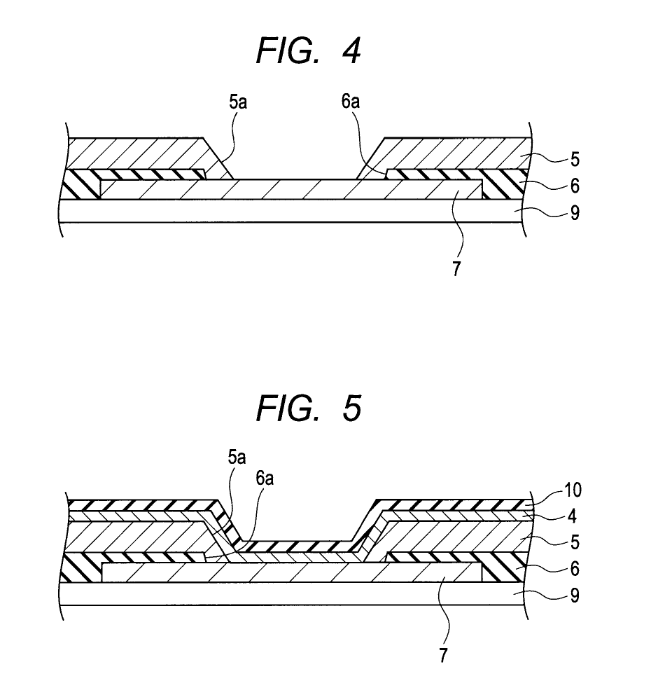

Then, a method of manufacturing a semiconductor device according to this embodiment is to be described. FIG. 4 to FIG. 8 are cross sectional views showing a series of steps for explaining the manufacturing method.

The manufacturing method for the semiconductor device according to this embodiment includes the steps of forming an insulative film (for example, protective resin film 5) on an electrode (electrode pad 7) where the insulative film has an opening 5a for exposing the electrode, forming an under bump metal (UBMS layer 3) on the insulative film so as to be connected with the electrode through the opening 5a, and forming a solder ball 1 on the under bump metal. The manufacturing method performs a step of forming the under bump metal and a step of forming the solder balls 1 such that the contour line 1a at the lower end of the ball 1 is situated inside the contour line 3a of the under bump metal. The method is to be described more specifically.

First, by using a general semiconductor manufacturing process, transistors 12 are formed to the substrate 11 and, further, the multi-layered wiring layer 16 having the configuration described above is formed above the transistors 12. The wirings at the uppermost layer of the multi-layered wiring layer 16 include the electrode pad 7. A cover nitride film 6 is formed on the electrode pad 7 and an opening 6a is formed to the cover nitride film 6 for exposing the electrode pad 7. Further, the protective resin film 5 is formed on the electrode pad 7 and on the cover nitride film 6, and an opening 5a for exposing the electrode pad 7 is formed also in the protective resin film 5 (FIG. 4).

Then, a Ti film 4 is formed as a barrier film over the electrode 7 and over the protective resin film 5 by sputtering, etc. Further, a Cu film 10 is formed on the Ti film 4 by sputtering or the like (FIG. 5). When the UBM layer 3 is formed by plating, the Cu film 10 serves as a seed for plating.

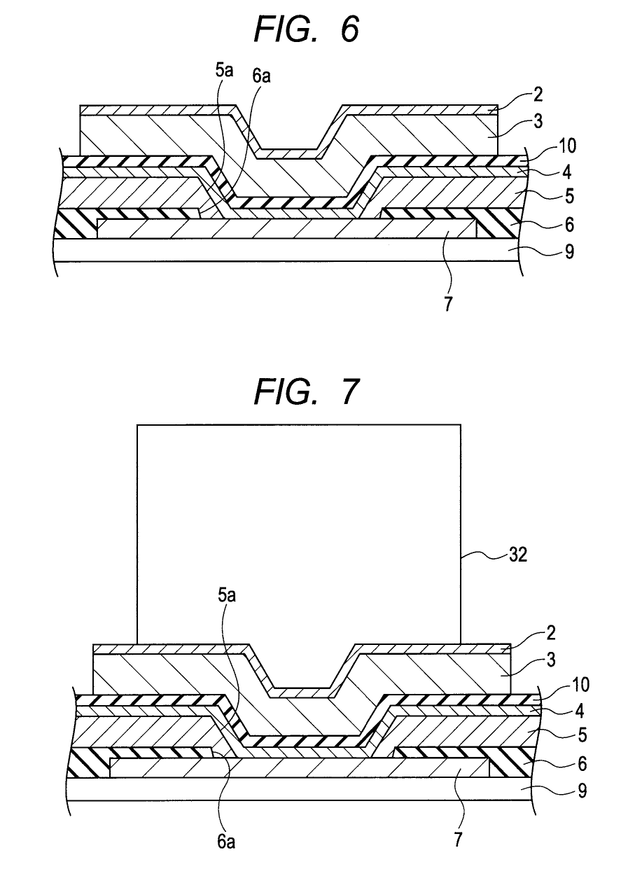

Then, the UBM layer 3 is formed on the Cu film 10. The UMB layer 3 is formed by forming a resist mask (not illustrate) on the Cu film 10 and forming an opening in the resist mask corresponding to the range of forming the UBM layer 3. Then, the UBM layer 3 is formed in the opening by a method, for example, plating (electrolytic plating) in the opening. The diametrical size of the UBM layer 3 is set larger than that of a solder layer 32 to be formed later (FIG. 7). For this purpose, the diameter for the opening of the resist mask used in the formation of the UBM layer 3 is made lager than that of a resist mask (to be described later) for forming the solder layer 32. After forming the UBM layer 3, a Cu film 2 is formed in the opening of the resist mask used for forming the UBM layer 3. Then, the resist mask is removed (FIG. 6).

Then, as shown in FIG. 7, a solder layer 32 is formed on the Cu film 2 by plating (electrolytic plating). For this purpose, a resist mask (not illustrated) having an opening with a diametrical size smaller than that of the resist mask for forming the UBM layer 3 is formed over the Cu film 2 and over the Cu film 10, for example, and the solder layer 32 is formed by plating (electrolytic plating) in the opening of the resist mask. Then, the resist masks are removed.

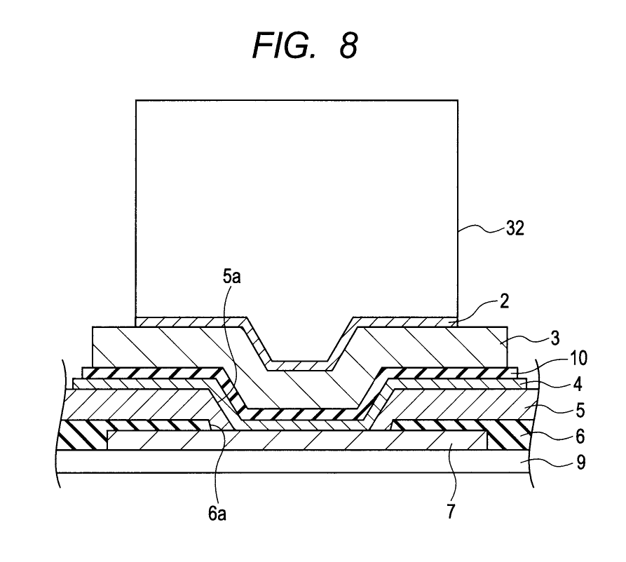

Then, as shown in FIG. 8, the Cu film 2 extended out of the solder layer 32, and the Cu film 10 and the Ti film 4 extended out of the UBM layer 3 are removed by performing wet etching for the entire surface.

Then, the solder ball 1 is formed by heating and ref lowing the solder layer 32 (FIG. 1). Thus, the semiconductor device according to this embodiment is obtained.

The solder ball 1 is formed so as to be in contact with the upper surface of the Cu film 2 having good wettability with the solder and is not in contact with the upper surface of the UBM layer 3.

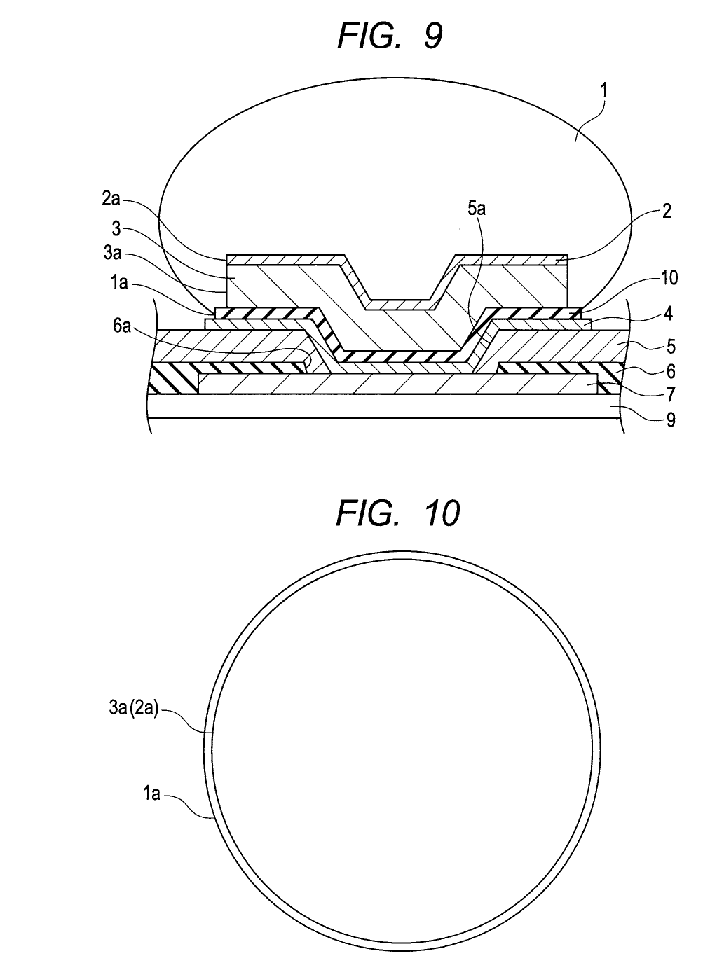

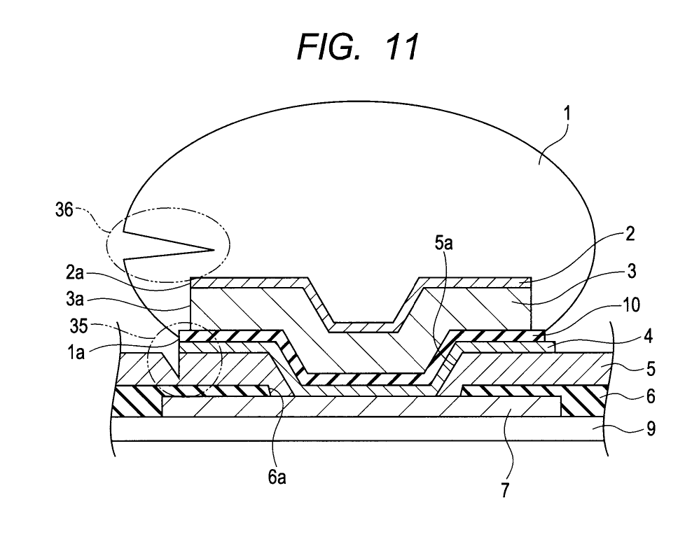

Then, the semiconductor device according to a comparative examination case is to be described. FIG. 9 is a cross sectional view of a semiconductor device according to the comparative examination case and FIG. 10 is a view showing a planar positional relationship between the contour line 1a at the lower end of the solder ball 1 and the contour line 3a of the UBM layer 3 of the semiconductor device according to the comparative examination case and FIG. 11 is a cross sectional view showing the problem in the semiconductor device of the comparative examination case.

As shown in FIG. 9, and FIG. 10, the semiconductor device according to the comparative examination case is different from the semiconductor device according to the embodiment described above only in that the contour line 3a of the UBM layer 3 corresponds to the contour line 2a of the Cu film 2 in a planar view, the contour line 1a at the lower end of the solder ball 1 is substantially corresponds to the contour line of the Cu film 10, and the contour line 1a and the contour line 3a substantially correspond in a planar view and the semiconductor device according to the comparative examination case is configured in the same manner as the semiconductor device according to the embodiment with respect to other points.

In the semiconductor device of the comparative examination case, a stress caused by the difference of the linear expansion coefficient between the semiconductor device and the mounting substrate concentrates to the peripheral edge of the UBM layer 3 in the cooling process after reflowing the solver ball 1 and mounting the semiconductor device to the mounting substrate. This is because the contour line 3a of the UBM layer 3 and the contour line 1a of the solder ball 1 substantially correspond to each other in a planar view. Accordingly, a rupture 35 is generated in the protective resin film 5 at a portion situated just below the peripheral edge of the UBM layer 3, or a rupture 36 is generated in the solder ball 11 at a portion situating above the peripheral edge of the UBM layer 3, for example, as shown in FIG. 11. Further, rupture may sometimes be generated also in the Low-k film in the lower layer (interlayer insulative films 18, 22, wiring layer insulative films 15, 20, 24: refer to FIG. 3) being triggered from the rupture 35 generated in the protective resin film 5. Rupture in the lower layer wirings can be observed by SAT observation (Scanning Acoustic Tomograph), which is referred to as a White Bump or White Spot.

In recent years, use of lead, mercury, cadmium, etc. to electronic equipments is inhibited in principle in the European Union and it is desired that the solder ball 1 should be shifted from the lead solder to the lead-free solder. The lead solder has high stress absorbing property since it has high ductility, whereas the lead-free solder has low stress absorbing property since it has lower ductility than the lead solder. Therefore, the fracture in the film or the fracture in the solder ball described above tends to occur.

On the contrary, in the semiconductor device according to the embodiment, the contour line 1a at the lower end of the solder ball 1 is situated inside the contour line 3a of the UBM layer 3 as shown in FIG. 1 and FIG. 2. In other words, the UBM layer 3 extends outward beyond the lower end of the solder ball 1. Therefore, the UBM layer 3 is interposed between the contour line 1a of the solder ball 1 and the protection resin film 5, and the stress transmitted from the peripheral edge of the solder ball 1 to the protective resin film 5 is moderated by the UBM layer 3. As a result, generation of the rupture in the protective resin film 5 can be suppressed. Therefore, the rupture of the Low-k film (interlayer insulative films 18, 22, and wiring layer insulative films 15, 20, 24; refer to FIG. 3) in the lower layer being triggered from the rupture in the protective resin layer film 5 can also be suppressed. Further, the rupture in the solder ball 1 at a portion situated above the peripheral portion of the UBM layer 3 can also be suppressed.

In the embodiment described above, since the contour line 1a at the lower end of the solder ball 1 formed over the UBM layer 3 is situated inside the contour line 3a of the UBM layer 3, when the stress that concentrates to the peripheral edge at the lower end of the solder ball 1 is transmitted by way of the UBM layer 3 to the protective resin film 5, the stress can be suppressed by the UBM layer 3. Therefore, the rupture in the protective resin film 5 can be suppressed and, further, generation of the rupture to the film in the layer lower than the protective film 5 being triggered from the rupture in the protective resin film 5 can also be suppressed. As described above, generation of the rupture in the protective insulative film 5 due to the stress upon mounting of the semiconductor device can be suppressed even in a case where the solder ball 1 is formed of the lead-free solder.

Further, in the structure of Japanese Unexamined Patent Publication No. Hei 06(1994)-177134 and Japanese Unexamined Patent Publication No. 2009-212332, since it is necessary to interpose the resin layer between the solder bump and the electrode for moderating the stress, thickness of the semiconductor device increases making it difficult to mount the semiconductor device to the package. On the contrary, in this embodiment, since the stress can be moderated upon mounting of the semiconductor device without additionally disposing the layer structure for moderating the stress, increase in the thickness of the semiconductor device can be suppressed.

In the embodiment described above, while explanation has been made to an example of forming the Cu film 2 on the UBM layer 3 and forming the solder layer 32 on the Cu film 2, Ni film (not illustrated: metal film comprising identical metal material with that of UBM layer 3) may be formed instead of the Cu film 2, and the solder layer 32 may be formed on the Ni film. In this case, the contour line 1a at the lower end of the solder ball 1 corresponds to the contour line for the joined surface between the solder ball 1 and the Ni film therebelow. In this case, after forming the Ni film and the solder layer 32 successively, resist masks used for forming the Ni film and the solder layer 32 are removed and then the solder layer 32 is subjected to ref lowing thereby forming the solder ball 1. In this case, growing of the Ni layer by plating and growing of the solder layer 32 by plating are performed in separate chambers respectively. When growing of the Ni layer by plating is switched to growing of the solder layer 32 by plating, the surface of the Ni layer may sometimes be exposed to atmospheric air. If the time of exposing the surface of the Ni layer to the atmospheric air is within several seconds, the solder layer 32 can be grown by plating over the Ni layer with no particular problem. However, when the surface of the Ni layer is exposed for a long time to the atmospheric air, since the surface of the Ni layer is oxidized slowly, growing of the solder layer 32 on the Ni layer by plating is difficult. Further, the diametrical size for the openings of the resist masks used for the Ni film and the solder layer 32 is made smaller than that of the resist mask used for the UBM layer 3, so that the contour lines of the Ni film and the solder layer 32 are situated inside the contour line 3a of the UBM layer 3 in a planar view. That is, an Ni mask of a shape identical with corresponding to the shape of the Cu film 2 shown in FIG. 8 is formed and a solder layer 32 of a shape identical with that shown in FIG. 8 is formed. Then, the surface of the UBM layer 3 extended to the outside of the Ni film and the solder layer 32 is oxidized by the wet treatment for removing the resist masks. Since the oxidized surface of the UBM layer 3 has no good wettability to the solder, when the solder layer 32 is subjected to reflowing, the oxidized surface of the UBM layer 3 can be kept from being contact with the solder ball 1. As a result, also in this case, a solder ball 1 having a shape identical with that shown in FIG. 1 can be formed.

In the embodiment described above, while explanation has been made to the example of forming the solder layer 32 by the plating method, the solder layer 32 may be formed also by printing. In this case, the solder layer 32 is formed after the step shown in FIG. 6, by disposing a printing plate on the Cu film 2 and burying the material for the solder layer 32 to a region for forming the solder layer 32 by a squeegee as shown in FIG. 7.

While the example of growing the UBM layer 3 and the Cu film 2 by plating has been explained in the embodiment described above, the UBM layer 3 and the Cu film 2 may be grown also by sputtering.

What is claimed is:

1. A semiconductor device comprising:
an electrode, an insulative film formed over the electrode and having an opening for exposing the electrode therethrough;
an under bump metal formed over the insulative film and connected through the opening with the electrode; and
a solder ball formed on the under bump metal,
wherein the contour line at the lower end of the solder ball is situated inside the contour line of the under bump metal.

2. The semiconductor device according to claim 1, further comprising:
a metal film formed on the under bump metal,
wherein the metal film has a wettability to a solder which is higher than that of the under bump metal, the contour line of the metal film is situated inside the contour line of the under bump metal, and
wherein the solder ball is in contact with the metal film.

3. The semiconductor device according to claim 2, wherein the metal film comprises Cu or a metal material identical with that of the under bump metal.

4. The semiconductor device according to claim 2, wherein the solder ball is in contact with the entire surface of the metal film.

5. The semiconductor device according to claim 1, wherein the diameter of the under bump metal is larger by 10 μm or more than the diameter at the lower end of the solder ball.

6. The semiconductor device according to claim 1, wherein the diameter of the under bump metal is 1.1 times or more of the diameter at the lower end of the solder ball.

7. The semiconductor device according to claim 1, wherein the under bump metal is an Ni layer.

8. The semiconductor device according to claim 1, wherein the solder ball comprises a lead-free solder.

9. The semiconductor device according to claim 8, wherein the lead-free solder is Sn—Ag solder or Sn—Ag—Cu solder.

10. The semiconductor device according to claim 1, wherein an interlayer insulative film situated in the layer below the electrode is provided, and the interlayer insulative film comprises a Low-k film.

11. A method of manufacturing a semiconductor device comprising:
forming an insulative film over an electrode, the insulative film having an opening for exposing the electrode, forming an under bump metal so as to be connected with the electrode through the opening; and
forming a solder ball over the under bump metal,
wherein the steps of forming the under bump metal and forming the solder ball are performed such that the contour line at the lower end of the solder ball is situated inside the contour line of the under bump metal.
